(19) United States
(12) Patent Application Publication
(10) Pub. No.: US 2006/0220094 A1
(43) Pub. Date: Oct. 5, 2006

(54) Non-volatile memory transistor with nanotube floating gate

(76) Inventor: Bohumil Lojek, Colorado Springs, CO (US)

Correspondence Address: SCHNECK & SCHNECK, P.O. BOX 2-E, SAN JOSE, CA, 95109-0005, US

(21) Appl. No.: 11/096,857

(22) Filed: Mar. 31, 2005

(51) Int. Cl. H01L 29/788

(52) U.S. Cl. 257/315

(57) ABSTRACT

Non-volatile memory transistors have a semiconductor substrate with spaced apart source and drain regions defining a channel, a layer of tunnel oxide over the channel and a conductive layer of carbon nanotubes over the tunnel oxide. In patterning, mesas are formed retaining desired locations of nanotubes as floating gates. The mesas are used for self-aligned implantation of source and drain electrodes. The nanotubes, being deposited as a porous randomly arranged matted layer, allow for etch removal of the support layer so that the nanotubes rest directly on tunnel oxide. The nanotubes are protected with insulative material and a conductive control gate is placed over the nanotube floating gate layer.

### TECHNICAL FIELD

The invention relates to transistor construction and, in particular, to non-volatile memory transistors incorporating nanotubes for charge storage.

### BACKGROUND ART

Non-volatile nanocrystal transistor memory cells are known. For example, U.S. Pat. No. 6,690,059 to B. Lojek describes a non-volatile memory transistor that uses a floating gate as a charge storage region, transferring charge through a tunneling barrier to nanocrystals. The device relies on a separate charge reservoir, which can be doped specifically for charge supply, while the substrate is doped for conductivity between source and drain electrodes. By pulling charge from the charge reservoir to a separated nanocrystal layer, the electrostatic properties of the nanocrystal web layer are modified, influencing a subsurface channel between source and drain in a MOS transistor. The nanocrystals are used to modify electrostatic properties of a separated region and then directly influence channel behavior in the usual way, characteristic of a MOS transistor. In the simplest mode of operation, a threshold may be established for charge transfer from the charge supply layer to the nanocrystal web layer and this threshold is similar to the threshold of non-volatile memory transistors. However, further voltage changes will cause further electron transitions from the charge supply layer to the nanocrystal web layer whereby the conductivity of the channel is changed in a stepwise manner, like modulation. Reverse voltages will cause depletion of the nanocrystal web layer, driving electrons from the nanocrystal web layer back to the charge supply layer. Conduction between source and drain amplifies the gate voltage in the amplifier mode or senses the pinch-off characteristic in the memory mode.

In U.S. Pat. No. 6,808,986 Rao et al describe a nanocrystal layer made using chemical vapor deposition. In U.S. Pat. No. 6,344,403 Madhukar et al describe a similar nanocrystal growth procedure.

An object of the invention is to provide a uniform, high density nanocrystal layer for more efficient charge trapping in a memory transistor.

### SUMMARY OF INVENTION

The above object has been achieved by growing carbon nanotubes in a matted layer over a tunnel oxide layer on a doped silicon wafer. The nanotube layer is grown by any known method of deposition of carbon nanotubes, for example, depositing catalyst particles, such as Mo, over the tunnel oxide and annealing. After annealing, a carbon containing gas, such as methane, is introduced by chemical vapor deposition (CVD) at moderate temperature. Conductive carbon nanotubes form as the carbon containing gas breaks down, adhering to the surface where catalyst particles lie. A matted nanotube woven structure or layer is randomly oganized and forms a kind of web lying over tunneling oxide. A protective silicon dioxide layer overlies and protectively embeds the nanotubes. The layer is patterned and etched to allow implantation of source and drain electrodes in the substrate. The nanotube layer is electrically floating above the channel region in a position to modulate or regulate conduction in the channel between source and drain electrodes. The nanotube and oxide layers are covered by a polysilicon conductive layer that acts as a control gate in insulated relation to the floating gate layer. All layers are then finished to form floating gate transistors.

### BRIEF DESCRIPTION OF THE DRAWINGS

FIGS. 1-8 are sequential side plan views of a method of making a nanocrystal charge storage layer in accordance with the present invention.

### BEST MODE OF CARRYING OUT THE INVENTION

With reference to FIG. 1, a silicon substrate 11 is shown having a planar surface 12 which is polished and not patterned. Most commercial silicon wafers already have adequate planarity from polishing, and further polishing is not needed. Substrate 11 is doped to have a desired conductivity for building transistors, preferably MOS or CMOS transistors.

On the surface 12 of the planar silicon substrate 11 a very thin high quality silicon dioxide surface layer 13 is deposited by any of the usual methods as a first insulating layer. This oxide layer, typically a thermal oxide layer, has a thickness in the range of 20 to 60 Angstroms. Such a thin oxide layer will serve as a tunnel oxide layer for a memory cell in which a conductive member resides above the oxide layer. In EEPROM memories, a typical floating gate is built above a thin oxide layer and for this purpose, the present invention contemplates a carbon nanotube web layer as the floating gate layer.

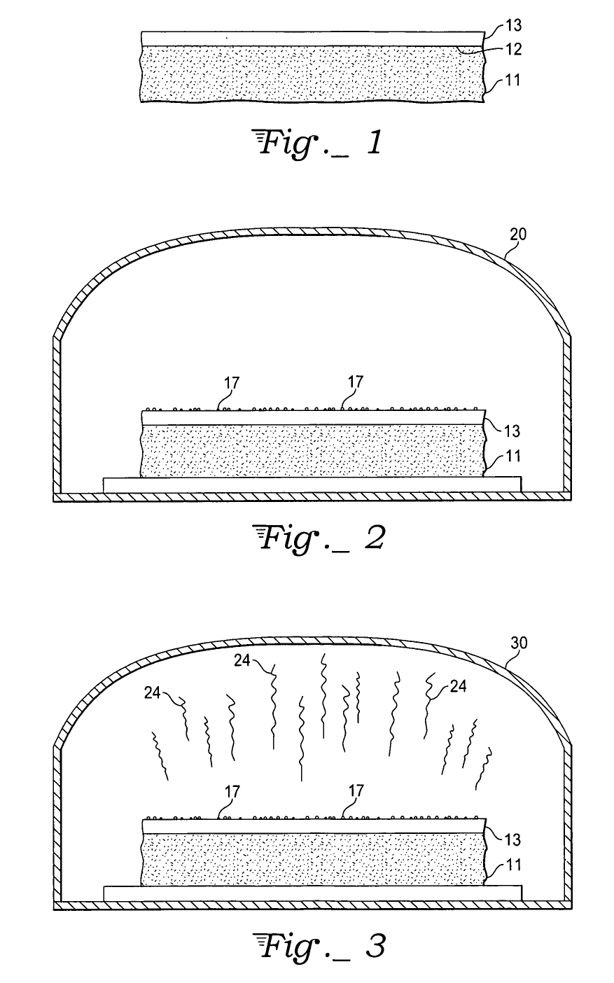

FIG. 2 shows an example of deposition of catalyst particles 17 sputtered or otherwise deposited in chamber 20. The particles are molecular aggregations having a density of a particle per 400 nm² or better thereby forming a non-contacting particle layer. Although some particles may be contacting, most particles are not contacting other particles. Because the tunnel oxide layer 13 is very fragile, oxide layer may be nitridized.

As an example of nanotube formation, in FIG. 3, a CVD chamber 30 has a carbon bearing gas 24 introduced into the chamber at moderate temperature. For example, methane (CH₄) may be introduced at 1000° C. The methane dissociates on contact with the catalyst particles, with the carbon reforming as carbon nanotubes, as described by J. Kong et al. in “Chemical Vapor Deposition of Methane for Single Walled Carbon Nanotubes” in Chemical Physics Letters, vol. 292, 14 Aug. 1998, pages 567-574. A significant fraction of the carbon nanotubes are conductive, while others are non-conductive. The nanotubes are matted, with randomly crossing nanotubes adhering to the silicon oxide layer, but somewhat porous with spaces between crossing nanotubes.

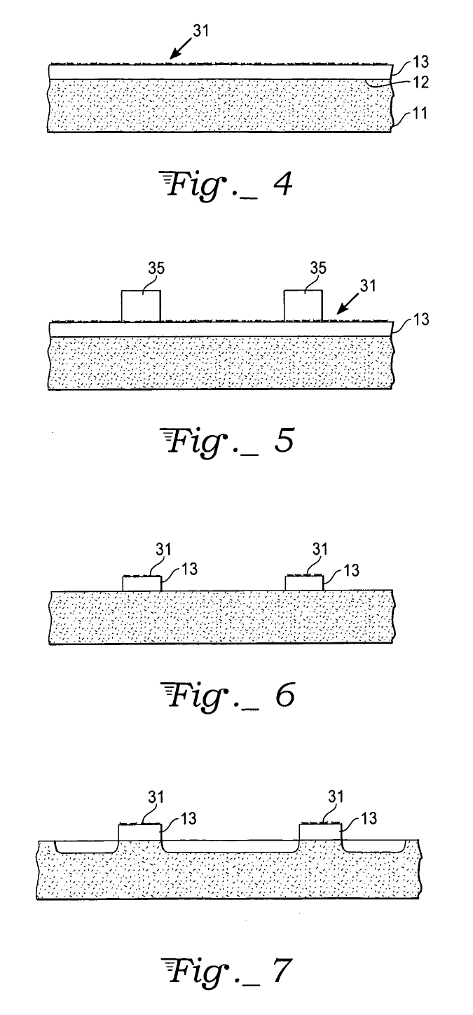

With reference to FIG. 4, a nanotube layer 31 is formed atop the silicon oxide layer 13. The nanotube layer 31 has nanotubes sufficiently dense to be conductive and matted, with fibers crossing each other in random directions, yet with some porosity through the matted structure. The layer of nanotubes 31 extends completely over the wafer and exhibits charge retention characteristics, similar to polysilicon, although many fibers may be insulative or semi-insulative.

In FIG. 5, the nanotube layer 31 has portions where floating gates are to be formed protected by insulative photoresist mesas 35. Portions between the mesas are exposed. These exposed portions, together with exposed nitride regions, are etched away down to the oxide layer 13, as shown in FIG. 6.

The oxide layer 13 is removed in unprotected areas and source ion implants 37 are introduced, together with the drain ion implant 39 using mesa edges for self-alignment of the implants. The source and drain ion implants are regions of excess dopants to the doped substrate that will form subsurface electrodes. Nanotube portions 31 lie atop tunnel oxide portions 13.

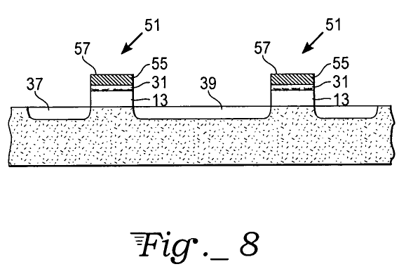

In FIG. 8, two transistors 51 and 53 are nearly completed. The nanocrystal layer portions 31 have been covered with protective oxide 55. The oxide 55 is an insulative thermal oxide about 60-100 Å. Polysilicon layer portions 57 are deposited over the nanotube layer portions 55. Each of the transistors 51 and 53 has a source 37 and drain 39 supplying charge particles to the floating nanotube layer portion 31 by tunneling or hot electron injection or other mechanisms through tunnel oxide layer 13. Charges transferred on to the floating gate layer by voltage applied to the control gate 57 through a metallization layer, not shown. An opposite voltage can transfer charge from the floating gate layer, with the floating gate layer formed above nanotubes storing charge for long periods of time except when programming is changed.

1. A floating gate non-volatile memory transistor comprising,
a semiconductor substrate having spaced apart source and drain electrodes in the substrate,
a layer of tunnel oxide above the substrate between the source and drain,
an electrically floating carbon nanotube web layer above the tunnel oxide, and
a conductive layer over the carbon nanotube layer.

2. The device of claim 1 wherein the carbon nanotube layer comprises matted nanotubes.

3. The device of claim 2 wherein a plurality of the matted nanotubes are conductive.

4. The device of claim 2 wherein a plurality of the matted nanotubes are semi-insulative.

5. The device of claim 1 wherein said conductive layer is a polysilicon layer.

6. The device of claim 1 wherein said semiconductor substrate has a first conductivity type and said source and drain electrodes have a second conductivity type.

7. The device of claim 1 wherein said carbon nanotube layer is embedded in an oxide layer.

8. The device of claim 1 wherein said conductive layer is a control gate having electrical charge control over the nanotube layer.

9. The device of claim 2 wherein said matted nanotube layer comprises nanotubes randomly overlying each other.

10. The device of claim 2 wherein said matted nanotube layer is porous.

11. In a floating gate memory transistor of the type having a source and drain in a semiconductor substrate, tunnel oxide above the substrate between the source and drain, a floating gate above the tunnel oxide and a control gate in insulated relation above the floating gate, the improvement comprising,
a plurality of carbon nanotubes embedded in insulative material forming the floating gate.

12. The device of claim 11 wherein the insulative material is an oxide of silicon.

13. An intermediate structure for use in making non-volatile memory transistors comprising,
a doped semiconductor wafer having a planar surface,
a layer of tunnel oxide over the planar surface,
a support layer over the tunnel oxide layer, and
a carbon nanotube layer deposited over the support layer.

14. The structure of claim 13 wherein the carbon nanotube layer, support layer and tunnel oxide layer have etched regions defining mesas with ion implantation regions in the wafer between the mesas.

15. An intermediate structure for use in making non-volatile memory transistors comprising,
a doped semiconductor wafer having a planar surface,
a layer of tunnel oxide over the planar surface,
a support layer over the tunnel oxide layer, and
a layer of nanotube-forming catalyst deposited over the support layer.
